(19) United States
(12) Patent Application Publication
(10) Pub. No.: US 2004/0228982 A1
(43) Pub. Date: Nov. 18, 2004

(54) Method for forming CVD film

(76) Inventor: Hiroshi Kawaura, Tokyo (JP)

Correspondence Address: FLYNN THIEL BOUTELL & TANIS, P.C., 2026 RAMBLING ROAD, KALAMAZOO, MI, 49008-1699, US

(21) Appl. No.: 10/692,655

(22) Filed: Oct. 24, 2003

(30) Foreign Application Priority Data
May 14, 2003 (JP) 2003-135540

(51) Int. Cl. C23C 16/00

(52) U.S. Cl. 427/569; 427/248.1

(57) ABSTRACT

The present invention provides a method for forming a uniform thickness vacuum CVD film on a surface of a substrate having a good step coverage and high quality. A process gas is supplied in a process chamber, which is closed by closing an exhaust port by closing a pressure control gate valve which is disposed between the process chamber and a vacuum pump. The process gas supply is stopped and a deposition on the substrate progresses for a certain period of time in the process chamber under pressure equilibrium closed condition. Thereafter or concurrently, in the same process chamber, an oxidizing gas or a nitrifying gas is supplied with plasma to oxidize or nitrify the formed film. By repetition of several cycles of these steps, a predetermined thickness film with high quality is obtained.

### FIELD OF THE INVENTION

The present invention relates to a method for forming CVD film in the field of semiconductor manufacturing process, such as silicone oxide film, silicone nitride film, metal oxide film or metal nitride film.

### PRIOR ARTS

In this technical field, a CVD film is formed in a vacuum process chamber at a constant reduced pressure. When the process gases are supplied, a pressure control valve (APC: Auto Pressure Control which is disposed between the process chamber and a vacuum pump is operated to control the pressure constant at vacuum. A general feature of the conventional process chamber is shown in FIG. 3.

The process chamber 4 has a gate valve 9, exhaust ports 11, 11 and a shower head 10, mounted on a upper part of the process chamber 4 facing the substrate (object to be processed), through which process gases are supplied and a high radio frequency is applied on the substrate. The pressure inside the process chamber is controlled by the pressure control valve (not shown) by constantly exhausting the inside gas from the process chamber through the exhaust ports 11, 11.

FIG. 6 shows a process flow chart indicating a CVD film formation process of the prior art. As shown, at first step of 601, a substrate is placed on a stage (susceptor) provided in a process chamber, next step at 602, the pressure in the process chamber is reduced to a predetermined level. At 603, a process gas is supplied by applying plasma, and at step 604, the gaseous material is deposited on the substrate surface while the process gas is continuously supplied.

Then at step 605, a process gas for oxidizing or nitrifying is supplied. The important point in these steps from 603 to 605 of CVD film formation process and oxidizing process, the pressure in the process chamber is always controlled at a constant reduced level, by way of exhausting gases inside the chamber via the exhaust ports 11, 11 controlling the pressure control valve.

After repeating several cycles of the above described steps from 603 to 605, the gas supply is stopped and the plasma is turned off at step 606, and at 607, the substrate is taken out from the process chamber.

In the prior art mentioned above, the gas flows inside of the process chamber as the process chamber is exhausted constantly to maintain the pressure at the predetermined reduced level during the CVD film formation process. The flow rate of the gas is rather fast which causes film formation rate difference between the center and the edge of the substrate (silicon wafer). Moreover, the film formation rate varies depending on the condition of the substrate surface, for instance, a step formed on the substrate surface changes the film formation rate.

In order to avoid the unpreferable effect of the gas flow inside the process chamber, and to spray uniformly the process gas over the substrate surface, the shower head (10 of FIG. 3) is disposed over the substrate, or many exhaust ports are formed around the substrate. However, it is difficult to prevent the effect of the gas flow inside the process chamber, and also there occurs another problem of particle contamination from the shower head. Moreover, the prior art can not be applicable to a large diameter substrate, or highly integrated semiconductor devices.

In the development of the recent semiconductor devices, the circuit becomes highly integrated and a wire size of the tip becomes very minute, it is difficult to obtain a good step coverage and uniform film surface, furthermore to obtain a good film characterstics by the conventional method.

Recently, in the film formation method by using gas plasma, high-density gas plasma is used for obtaining an excellent film. For example, to generate high-density plasma, ECR (Electron-Cycrotoron-Resonannce), TCP (Transformer-Coupled-Plasma), or Helicon are proposed. However, they do not have a gas ejecting means like a shower head facing the substrate to be processed in a process chamber, nozzles are arranged along the periphery of the upper part of the process chamber to supply a gas uniformly on the substrate to be processed. But it takes a quite time to design a proper arrangement of the nozzles depending on a inside pressure, a gas flow rate and plasma source for film forming process.

### SUMMARY OF THE INVENTION

An objective of the present invention is to provide a novel method for forming uniform CVD film which has good step coverage, uniform thickness and high quality characteristics.

The present invention provides a method and an apparatus for forming a uniform thickness CVD film with high quality, in which at the material gas supply step, the process chamber is closed by closing a pressure control valve between the process chamber and the exhaust port, and even after stopping the process gas supply, a deposition on a substrate is progressed in a process chamber under pressure equilibrium condition. Successively in the same process chamber, a gas for oxidizing or nitrifying is supplied with plasma application on the substrate to oxidize or nitrify the film on the surface of the substrate. By repeating several cycles of these steps (procedures), or a one cycle treatment, a uniform predetermined thickness film is obtained.

### BRIEF DESCRIPTION OF THE DRAWINGS EMBODIMENT

FIG. 1 is a schematic plan view of a process chamber of the present invention for forming CVD film by applying helicon plasma.

FIG. 2 is a sectional view of the process chamber of FIG. 1.

FIG. 3 is a sectional view of a process chamber having a shower head the prior art.

FIG. 4 is a process flow chart of an embodiment 1 of this invention.

FIG. 5 is a process flow chart of an embodiment 2 of this invention

FIG. 6 is a process flow chart of the prior art for producing CVD film.

### DETAILED DESCRIPTION OF THE PREFERRED EMBODIMENTS

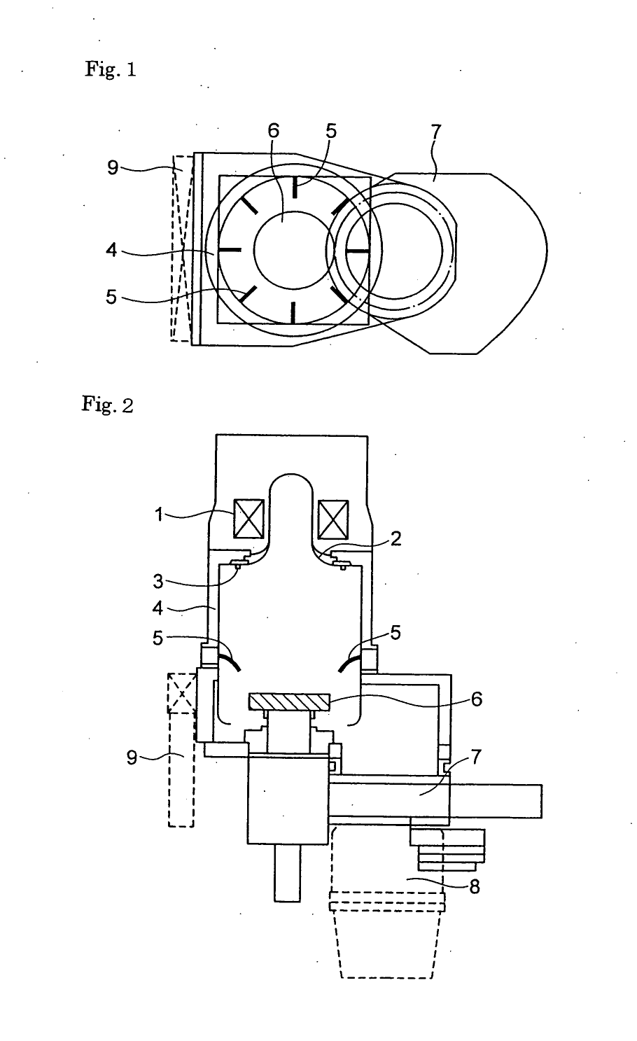

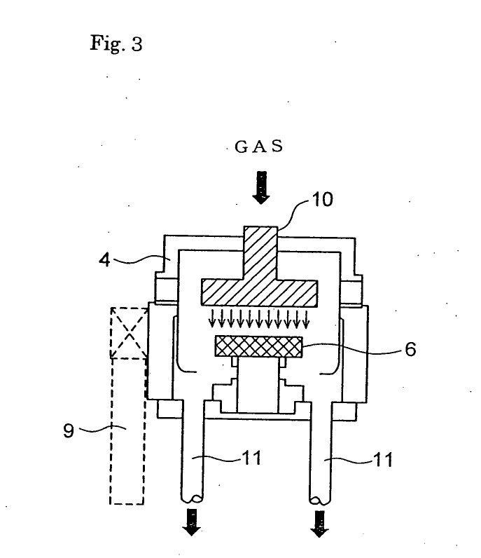

FIG. 1 is a schematic plan view of a process chamber of the present invention for forming CVD film by applying helicon plasma and FIG. 2 is a sectional view of the process chamber of FIG. 1.

In these figures, number 1 indicates an electromagnetic coil formed around the high frequency antenna (not shown) for generating a helicon wave, which is placed at a top of a dome type high-frequency transparent quarts belljar 2 (process chamber). Gas supplying nozzles 3 are disposed at a lower part of the quarts belljar 2, from which an oxygen gas, nitrogen or ammonium gas is supplied inside the belljar 2 to form a film. A gas-introducing pipe connected to the nozzles 3 is not shown.

Number 4 indicates a process chamber, and as shown in FIG. 1, 5 is a process gas supplying nozzles which are arranged equidistantly around the circumference of the belljar 2. In FIG. 2, a plurality of nozzle 5 is illustrated as having an angle with respect to the substrate to be processed, a numerous variations as to a number of the nozzles and an angle of the nozzles, unless the nozzles 5 are not affected by the gas plasma. A heater stage 6 is provided inside the process chamber 2 on which the substrate (semiconductor wafer) is heated.

A large diameter pressure control gate valve 7 has a pressure control means and is able to close the exhaustion port from the vacuum pump disposed under the pressure control gate valve 7. There is provided a turbo molecular-pump 8 which reduces the pressure of the process chamber to vacuum. A gate valve 9 for opening the process chamber to handle the substrate (wafer) is connected to a load-lock chamber (not shown).

A plasma source of helicon wave for CVD film forming apparatus, generates helicon wave (whistler wave) by a helicon wave antenna and an electromagnetic coil 1, and a high-density plasma having a density of 10 E11˜10E13/cm³ is generated.

In general, the plasma density of the conventional plasma generating apparatus of parallel flat type is about 10E9/cm³, but in the plasma generating apparatus used in this embodiment, a plasma density is 2 to 4 orders larger than the conventional plasma generating apparatus. The high-density plasma is transmitted along magnetic field generated by the electromagnetic coil 1, and supplies high-density reactive species on the substrate with an ion impact. Thus organic compounds on the stage 6 are disassociated and removed effectively compared with the method of high thermal CVD film formation or parallel flat type plasma CVD film formation.

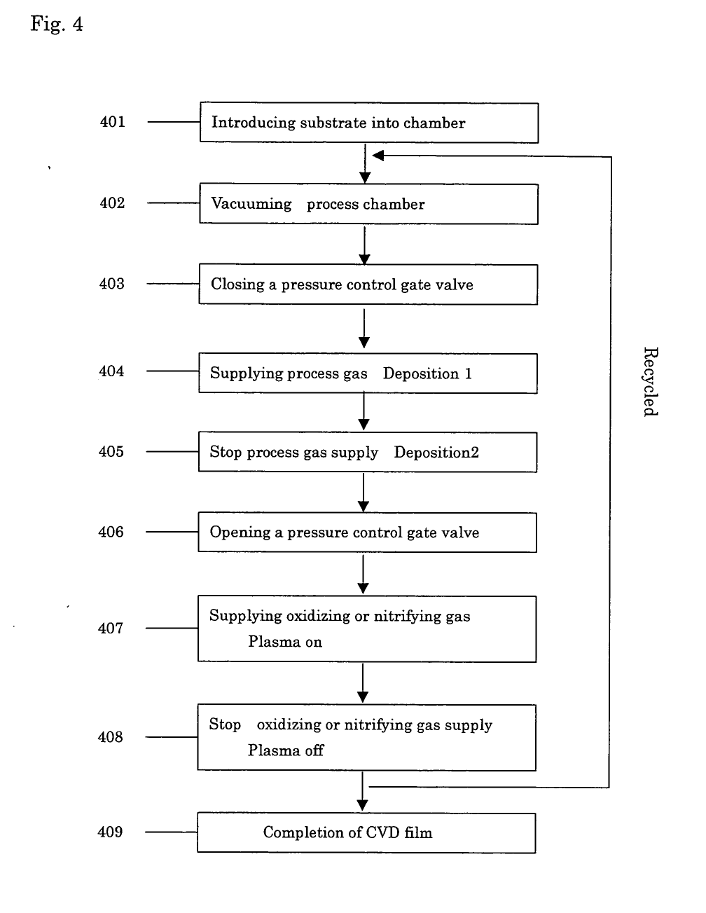

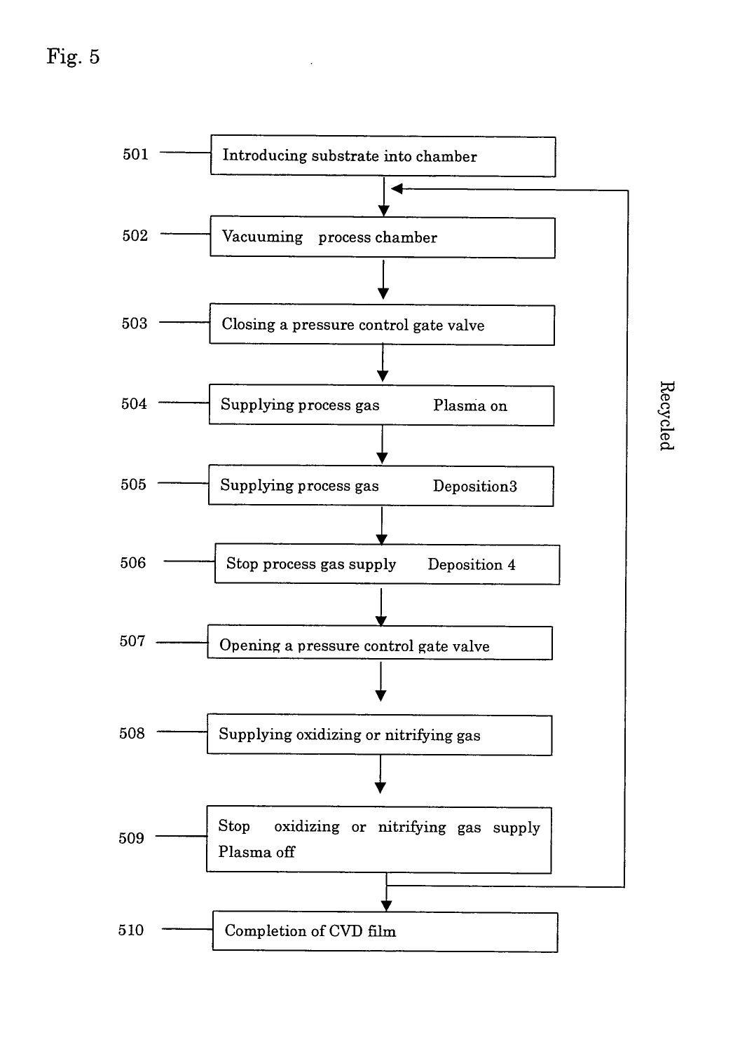

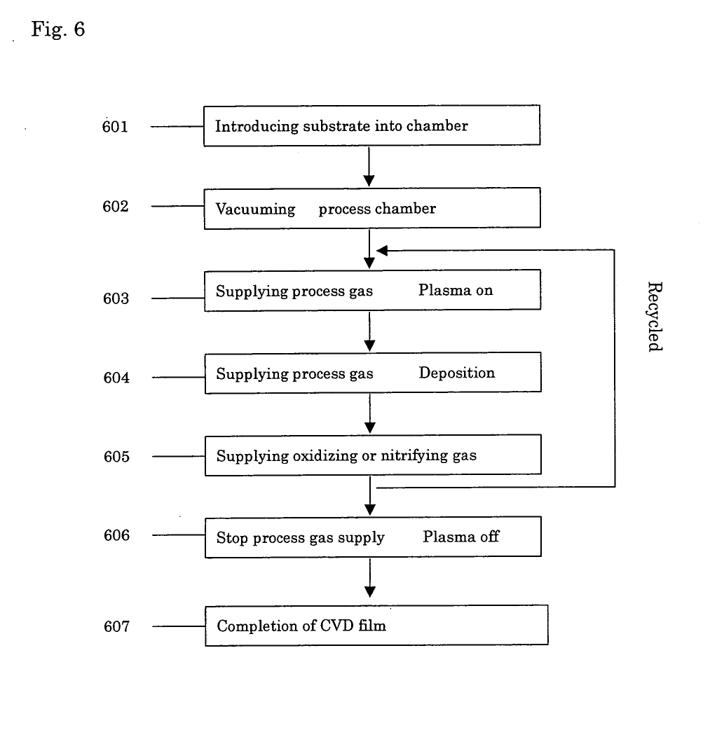

FIGS. 4 and 5 show a process flow chart showing a CVD film forming process of the present invention.

FIG. 4 indicates a remarkable point of the present invention, that is the process for forming CVD film is performed in a closed condition by closing a pressure control gate valve 7. With supplying a process gas to the process chamber 4, the internal pressure of the process chamber 4 rises during deposition process, and after the process gas supply is stopped, under pressurized condition, uniform deposition is progressed over the steps of the surface of the substrate.

First, the substrate is introduced in the process chamber 4 at step 401 of FIG. 4, the process chamber 4 is reduced at step 402. When the process chamber 4 is reduced to a predetermined degree, a pressure control gate valve 7 is closed at step 403. Next step 404, a process gas is supplied into the process chamber 4 at the reduced pressure, then the pressure in the process chamber rises depending on an amount of the gas introduced into the process chamber, and the deposition process 1 on the substrate surface proceeds in the closed condition.

At step 405, when the process gas supply is stopped, the pressure inside the process chamber is maintained constant, and the deposition process 2 proceeds during this step 405. Next step 406, the pressure control gate valve 7 is opened to reduce the internal pressure in the process chamber, and at step 407 a gas for oxidizing or nitrifying is supplied with plasma in the process chamber. At step 408, the oxidizing gas or nitrifying gas supply is stopped and also the plasma application is stopped. Repeating several cycles of these steps (procedures), a uniform thickness film is formed on the substrate at step 409.

FIG. 5 shows a process flow chart showing another process of forming CVD film of present invention. The difference from the process in FIG. 4 is that in the deposition process, the plasma is applied in the process chamber. In FIG. 5, plasma is applied from the first step 504 with a process gas supply, and the rest of the procedures of FIG. 5 are the same as the process in FIG. 4. In both embodiments, the process chambers are not exhausted during the deposition process.

Referring to FIG. 5, a substrate is introduced in the process chamber 4 at step 501, the pressure in the process chamber 4 is reduced to vacuum by exhausting the gas in the process chamber by the turbo-molecule pump 8 through the pressure control gate valve 7 at step 502. Then the pressure control gate valve 7 is closed at step 503 and a process gas is supplied in the process chamber 4 under vacuum condition at step 504, consequently the internal pressure in the process chamber 4 rises at step 504 and a plasma is applied simultaneously with the process gas supply so further deposition proceeds in a closed gas-plasma atmospheric condition at 505.

At step 506, the process gas supply is stopped although the plasma is still applied continuously, so the internal pressure in the process chamber is kept at constant level and still the deposition proceeds in gas-plasma atmospheric condition. Next step 507, the pressure control gate valve 7 is opened to reduce the internal pressure in the process chamber 4, and at step 508, a oxidizing or nitrifying gas is supplied, at step 509, the oxidizing or nitrifying gas supply is stopped and also the plasma application is stopped.

Repeating several cycles of these steps from 502-509, a uniform thickness film is obtained at step 510. In this embodiment of FIG. 5, the plasma is applied continuously in the process chamber through the steps of 504˜509.

In the present invention, it is easy to change the gas species or power of plasma, and capable of continuing the process in the same chamber.

Difference between the process of FIG. 4 and FIG. 5 is a duration time of plasma application and in both processes, the process chambers are not vacuumed during the deposition process neither.

During the deposition process in gas plasma condition, gas plasma stimulates the dissociation of organic materials and is capable of shortening the deposition process time, and obtaining the excellent film.

In either embodiment, it is difficult to manufacture a high quality CVD film only by the process gas deposition, therefore the oxidizing or nitrifying process accompanied by heating or plasma application after the deposition, which removes the impurities (organic matters), is preferred.

1. A method for forming a CVD film under a vacuum, in which introduction of a process gas in a process chamber and exhaustion from the process chamber is not executed simultaneously.

2. A method for forming a CVD film under a vacuum, in which introduction of a process gas in a process chamber or oxidizing or nitrifying the film formed on a substrate process, and exhaustion from the process chamber is not executed simultaneously.

3. A method for forming a CVD film according to claim 1, wherein the inside the process chamber is an oxygen or nitrogen plasma condition when the process gas is introduced therein.

4. A method for forming a CVD film according to claim 1, wherein the gas plasma is applied continuously on the substrate in the same process chamber after the introduction of the process gas in the process chamber in order to improve the film characteristics.

5. A method for forming a CVD film according to claim 1, wherein the process after the introduction of the process gas is repeated in the same process chamber in order to obtain a uniform predetermined thickness film.

6. A method for forming a CVD film according to claim 1, wherein the plasma reactor is a helicon wave reactor.
